(19) United States
(12) Patent Application Publication
(10) Pub. No.: US 2026/0090379 A1
(43) Pub. Date: Mar. 26, 2026

(54) CHIP PACKAGING STRUCTURE AND PREPARATION METHOD

(71) Applicant: SJ Semiconductor(Jiangyin) Corporation, Jiangyin (CN)

(72) Inventors: Yenheng CHEN, Jiangyin (CN); Chengchung LIN, Jiangyin (CN); Jin YANG, Jiangyin (CN)

(73) Assignee: SJ Semiconductor(Jiangyin) Corporation, Jiangyin, JS (CN)

(21) Appl. No.: 19/108,744

(22) PCT Filed: Jun. 8, 2023
(86) PCT No.: PCT/CN2023/099210

§ 371 Date: Mar. 5, 2025

(30) Foreign Application Priority Data
Sep. 6, 2022 (CN) 202211081389.8

(51) Int. Cl. H01L 23/373; H01L 23/00; H01L 23/24; H01L 23/367

(52) U.S. Cl. CPC H10W 40/251; H10W 40/22; H10W 40/258; H10W 72/073; H10W 72/30; H10W 72/07338; H10W 72/324; H10W 72/352; H10W 72/354; H10W 76/47; H10W 90/736

(57) ABSTRACT

A chip packaging structure includes, a chip on a substrate; an enclosure structure on the chip, a wall of the enclosure structure comprises a sealed cavity, and the chip is revealed through the sealed cavity; a layer of thermal interface material for the chip, formed by filling a liquid metal into the sealed cavity of the wall of the enclosure structure; and a heat sink, formed on the layer of thermal interface material, is hermetically sealed to the wall of the enclosure structure. The heat sink component is formed on the layer of the thermal interface material, sealed and connected to the enclosure structure. The enclosure structure using flexible materials to prevent the liquid metal from overflowing in the encapsulation and application process, thereby reducing degradation. The UV curing adhesive is used for sealing and fixing the connection to the thermal interface material layer, so the disassembly and replacement of the process is simpler.

### TECHNICAL FIELD

The present invention relates to the field of semiconductor packaging technology, and in particular, relates to a chip packaging structure and a preparation method.

### BACKGROUND

Integrated Circuit (IC, also known as a chip) is widely used in modern electronic systems, computer systems, and communication systems. According to different application areas, the industry generally classifies ICs into digital chips, analog chips, memory chips, RF chips, power chips, optical chips, passive chips and so on. Among them, logic systems, computing systems, and communication systems composed of digital chips and memory chips which have been leading the development of IC manufacturing and its integration technology.

With the continuous development of advanced packaging technology, high-end server power also continues to rise, and systems for AI GPUs are even consuming more than 1,000 W. So, chip's heat dissipation has become particularly important in the face of the present situation. Currently, the commonly used heat dissipation technology is to adhere the thermal interface material (TIM) to the chip surface in order to dissipate the heat generated by the chip to the outside world. The current TIM mainly contains polymer, but the thermal conductivity of polymer TIM is relatively poor, which leads to poor heat dissipation of the package structure.

### SUMMARY

The present invention provides a chip packaging structure and a preparation method for solving the current problem of poor heat dissipation effect of semiconductor packaging structure leading to a decline in the performance of the packaging structure.

The present invention provides a method of preparing a chip encapsulation structure, the method of preparation comprises the following steps:
providing a substrate;
bonding a chip to the substrate, wherein the chip is electrically connected to the substrate;
fixing an enclosure structure on the chip, wherein the enclosure structure seals and connects to the chip, wherein the enclosure structure comprises a sealed cavity exposing the chip;
filling the sealed cavity with liquid metal to form a layer of thermal interface material disposed on the chip in conjunction with the enclosure structure;
forming a heat sink member on the layer of thermal interface material, and the heat sink member is sealed and fixedly connected to the enclosure structure;

Optionally, further comprising the step of forming a dummy chip on the substrate, the dummy chip being symmetrically distributed on both sides of the chip and fixedly connected to the substrate.

Optionally, the material of the liquid metal comprises one of gallium, indium, or tin.

Optionally, the enclosure structure is made of a flexible material, including one of foam, PDMS or EPDM.

Optionally, the heat dissipation component comprises a heat dissipation cover or a heat dissipation element, the heat dissipation element comprising a heat dissipation base, and heat dissipation fins disposed in a uniform arrangement on the heat dissipation base.

Optionally, the enclosure structure is sealed and fixedly connected to the chip by a UV curing adhesive; and the enclosure structure is sealed and fixedly connected to the heat dissipation component by a UV curing adhesive.

Optionally, the substrate comprises a wafer-level substrate.

The present invention also provides a chip package structure, the chip package structure comprising:
Baseboards;
a chip disposed on the substrate and electrically connected to the substrate;

A thermal interface material layer comprising an enclosure structure and a liquid metal, the enclosure structure being disposed on the chip and sealed and fixedly connected to the chip, and the enclosure structure having a sealed cavity revealing the chip, the liquid metal being disposed in the sealed cavity;

A heat dissipating member, formed on the layer of thermal interface material, and the heat dissipating member sealed and fixedly connected to the enclosure structure;

Optionally, the chip package structure further comprises dummy chips fixedly connected to the substrate and symmetrically distributed on both sides of the chip.

Optionally, the heat dissipation component comprises a heat dissipation cover or a heat dissipation element, the heat dissipation element comprising a heat dissipation base, and heat dissipation fins disposed in a uniform arrangement on the heat dissipation base.

As described above, the chip packaging structure and the preparation method of the present invention, the chip packaging structure comprises a substrate, a chip, a thermal interface material layer and a heat dissipation component, wherein the chip is disposed on the substrate and is electrically connected to the substrate, the thermal interface material layer comprises a enclosure structure and a liquid metal filled in a sealed cavity of the enclosure structure, the enclosure structure is disposed on the chip and is sealed and fixedly connected to the chip, and the heat dissipation component is formed on the thermal interface material layer, and the heat dissipation component is sealed and fixedly connected to the enclosure structure, so as to form a liquid metal containing liquid metal between the heat dissipation component and the chip by the enclosure structure. The enclosure structure is disposed on the chip and sealed and fixedly connected to the chip, the heat sink member is formed on the thermal interface material layer and the heat sink member is sealed and fixedly connected to the enclosure structure, thereby forming a thermal interface material layer containing liquid metal disposed between the heat sink member and the chip through the enclosure structure. The present invention reduces the thermal resistance of the encapsulation by introducing liquid metal as the thermal interface material, thereby substantially improving the thermal diffusion efficiency in the encapsulation process; the enclosure structure prepared using flexible materials prevents the liquid metal from overflowing in the encapsulation and application process, thereby reducing the probability of the resulting degradation of the electrical properties of the device, and the removal and replacement process is simple and effective due to the use of UV curing adhesive sealing to securely connect the layer of thermal interface material. Replacement process is simple and effective

### BRIEF DESCRIPTION OF THE DRAWINGS

FIG. 1 shows a flow chart of a method of preparing a chip package structure in an embodiment of the present invention.

FIG. 2 shows a schematic cross-sectional view of a substrate provided by an embodiment of the present invention.

FIG. 3 shows a schematic a cross-sectional view after bonding a chip provided by an embodiment of the present invention.

FIG. 4 shows a schematic cross-sectional diagram of the dummy chips provided by an embodiment of the present invention.

FIG. 5 shows a schematic cross-sectional view of the formation of a UV-curable adhesive provided by embodiments of the present invention.

FIG. 6 shows a schematic cross-sectional diagram after forming a layer of thermal interface material according to an embodiment of the present invention.

FIG. 7 shows a structural schematic diagram of a chip packaging structure provided by an embodiment of the present invention.

FIG. 8 shows a schematic structural diagram of another chip package structure provided by an embodiment of the present invention.

### REFERENCE NUMERALS

101: substrate, 102: chip, 103: dummy chip, 104: UV-curable adhesive, 105: thermal interface material layer, 1051: enclosure structure, 1052: liquid metal, 106: heat dissipation cover, 108: heat dissipation element, 1081: heat dissipation base, 1082: heat dissipation fins, S1˜S5: steps.

### DETAILED DESCRIPTION OF THE PREFERRED EMBODIMENTS

The specific embodiments are described below to illustrate the implementation of the present disclosure, and those skilled in the art can easily understand other advantages and effects of the present disclosure from the content disclosed in this specification. The present disclosure can also be implemented or applied in other specific embodiments. The details provided in this description can be modified or altered in various ways based on different perspectives and applications without departing from the spirit of the present disclosure.

For ease of description, spatial relationship terms such as “under,” “below,” “below,” “below,” “below,” “above,” “above,” “above,” and the like may be used herein to describe the relationship of an element or feature shown in the accompanying drawings to other elements or features., “above,” “on,” and the like to describe the relationship of one element or feature shown in the accompanying drawings to other elements or features. It will be appreciated that these spatial relationship terms are intended to encompass orientations of the device in use or operation other than those depicted in the accompanying drawings. Furthermore, when a layer is to be “between” two layers, it may be the only layer between the two layers, or there may be one or more intervening layers.

Refer to FIGS. 1 through 8. It is to be noted that the illustrations provided in this embodiment only illustrate the basic concept of the present invention in a schematic manner, so that the illustrations only show the components related to the present invention and are not drawn in accordance with the actual implementation of the number of components, shapes, and sizes of the actual implementation of the components of the type, number and proportion of the actual implementation of the components may be an arbitrary change, and the layout of the components of the type may be more complex.

### Embodiment 1

Referring to FIGS. 1 to 8, the present invention provides a method of preparing chip package structure comprising the following steps:
S1: provide a substrate 101;
S2: bonding a chip 102 on the substrate 101 and the chip 102 is electrically connected to the substrate 101;
S3: forming an enclosure structure 1051 to contain the chip 102 in a fixed position, wherein a wall of the enclosure structure 1051 comprises a sealed cavity, and the chip is revealed through the sealed cavity in the wall;
S4: filling the sealed cavity in the wall of the enclosure structure 1051 with a liquid metal 1052 to form a layer of thermal interface material 105 for the chip 102;
S5: forming a heat sink on the layer of thermal interface material 105, wherein the heat sink is hermetically sealed to the wall of the enclosure structure 1051.

The method of preparing the chip package structure described in relation to the chip package structure is further described below in conjunction with the accompanying drawings, as follows:

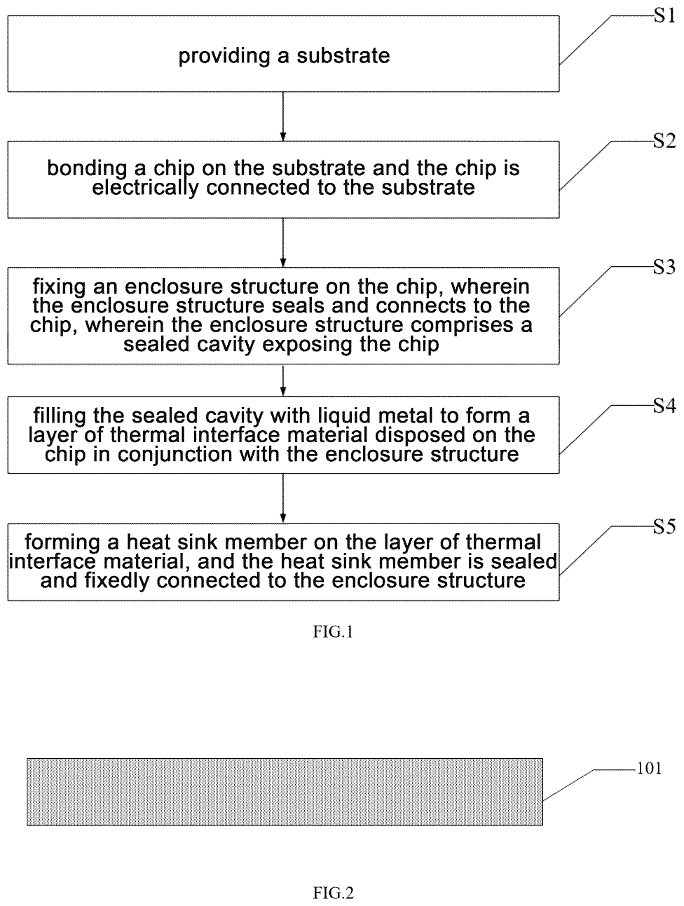

In step S1, referring to FIGS. 1 and 2, the substrate 101 is provided.

Optionally, the substrate 101 comprises a wafer.

Optionally, the substrate 101 comprises one of a silicon oxide substrate, a glass substrate, a ceramic substrate, and an organic substrate, which may be shaped as a circle, a square, or any other desired shape, and whose surface area is based on being able to carry the subsequent encapsulation structure.

Specifically, in this embodiment, the substrate 101 is selected as an organic substrate with a lower coefficient of thermal expansion, and the organic substrate has a lower coefficient of thermal expansion, which reduces warping generated during the encapsulation process.

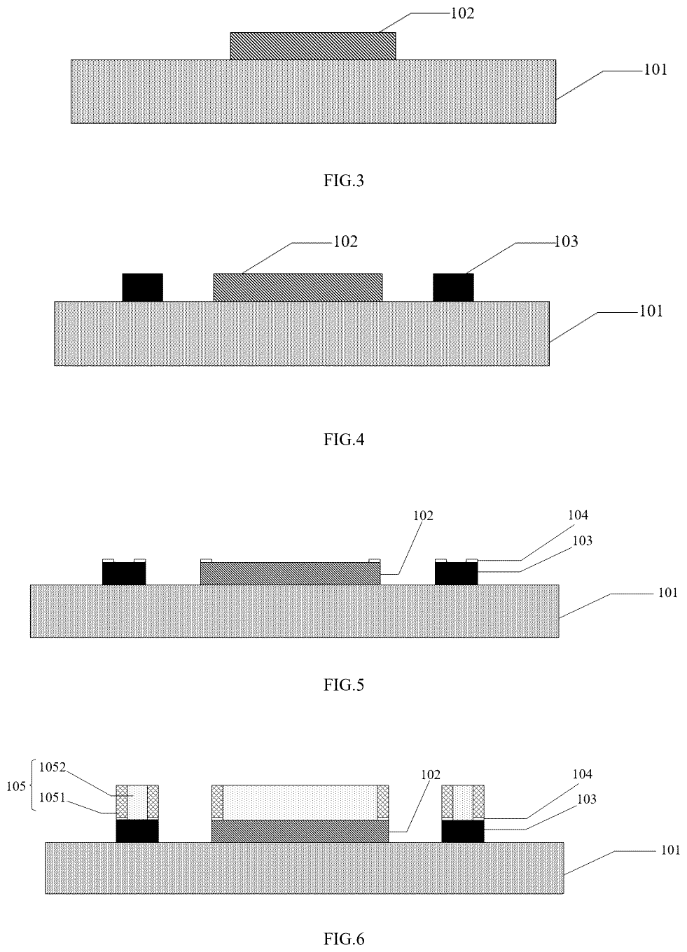

In step S2, referring to FIGS. 1 and 3, a chip 102 is bonded to the substrate 101 and the chip 102 is electrically connected to the substrate 101.

Optionally, as shown in FIG. 3, the chip 102 may be any existing semiconductor chip suitable for packaging, and may be a plurality of chips of the same type or of a plurality of different types, e.g., it may be a system-on-a-chip (SOC) device, or it may be a memory chip such as an HBM, etc., and is not limited herein. In addition, based on the requirements of packaging efficiency, packaging size, etc., a plurality of the chips 102 are generally packaged at the same time, and in this embodiment, the number of the chips 102 is shown as 1. However, the number of the chips 102 is not limited thereto, and the number of the chips 102 may be greater than or equal to 1 according to the requirements, for example, 2, 3, 4, or more.

Specifically, as shown in FIG. 4, further comprising the step of forming a dummy chip 103 on the substrate 101, the dummy chip 103 preferably being symmetrically distributed on both sides of the chip 102 and sealed and fixed to the substrate 101 to reduce the deformation of the package structure by the dummy chip 103, wherein the dummy chip 103 is a passive chip, the dummy chip 103 is sealed and fixed to the substrate 101 sealed fixed connection, the connection method is not limited to adhesive connection, in this embodiment the number of dummy chips 103 is shown is two, but the number of dummy chips 103 is not limited to two, but is set according to the demand, so the number of dummy chips 103 may be greater than or equal to 2, such as 3, 4 or more. wherein the step of forming the dummy chip 103 may be bonded to the substrate 101 before, after, or at the same time as the chip 102, without limitation herein.

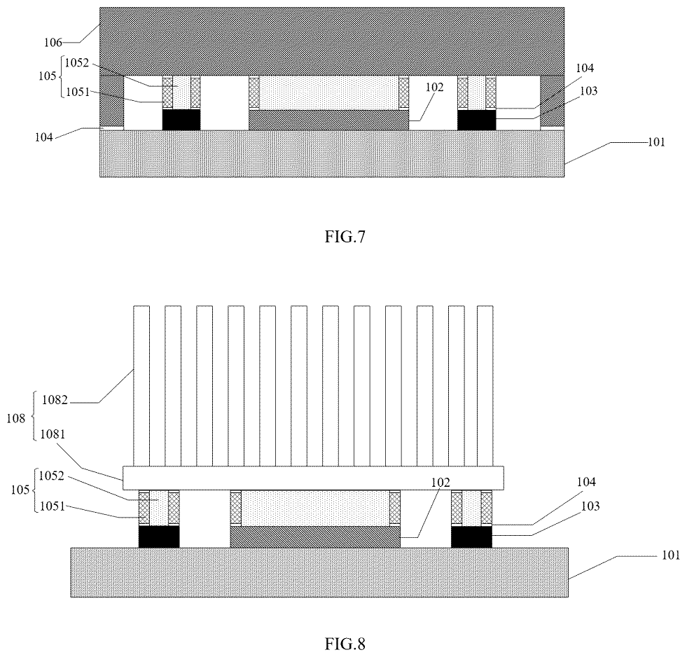

In step S3, referring to FIG. 1, FIG. 5, and FIG. 6, an enclosure structure 1051 is formed on the chip 102, the enclosure structure 1051 is sealed and fixedly connected to the chip 102, and the enclosure structure 1051 has a sealed cavity that reveals the chip 102.

Specifically, as shown in FIG. 6, the enclosure structure 1051 is sealed and fixedly connected to the chip 102 and the dummy chip 103 by means of a UV curing adhesive 104, and a sealed cavity is formed between the enclosure structure 1051 and the chip 102 and the dummy chip 103, the sealed cavity being capable of revealing the chip 102 and the dummy chip 103, respectively.

In this embodiment, as in FIGS. 5 and 6, the enclosure structure 1051 is fixedly connected to the chip by using the UV curing adhesive to seal and fix the connection, but the type of bonding adhesive is not limited to this, and other gels may be used as well. When the ultraviolet curing adhesive 104 is employed for the fixing operation, it may comprise dispensing the ultraviolet curing adhesive 104 to the top of the chip 102 and the dummy chip 103, the enclosure structure 1051 being fixed on the top of the chip 102 and the dummy chip 103, irradiating the ultraviolet curing adhesive 104 using ultraviolet light of a desired wavelength, and upon irradiation by ultraviolet light, the ultraviolet curing adhesive 104 can be quickly cured and molded, thereby sealing and fixing the enclosure structure 1051 above the corresponding chip.

Further, when it is necessary to repair or remove the enclosure structure 1051, it is only necessary to remove the UV curing adhesive 104 using acetone or other solvent having the same function to enable repair or safe removal of the enclosure structure 1051, without causing secondary damage to other parts in the process. Optionally, the enclosure structure 1051 is made of a flexible material, including one of foam, PDMS (polydimethylsiloxane), or EPDM (ethylene propylene diene rubber).

Specifically, in this embodiment, the material of the enclosure structure 1051 is preferably PDMS that is corrosion resistant, has high dielectric strength, and excellent compatibility with the chip 103.

In step S4, referring to FIGS. 1 and 6, liquid metal 1052 is filled in the sealed cavity to form a thermal interface material layer 105 disposed on the chip 102 in conjunction with the enclosure structure 1051.

Specifically, as shown in FIG. 6, filling the sealed cavity with liquid metal 1052, the liquid metal 1052 in combination with the enclosure structure 1051 together constituting the thermal interface material layer 105, the thermal interface material layer 105 being sealed and fixed to the chip 102 and the dummy chip 103 by the UV curable adhesive 104.

Optionally, the material of the liquid metal 1052 comprises one of gallium, indium, or tin.

Specifically, gallium, indium, or tin as a common liquid metal, its thermal conductivity is generally greater than 30 W/(m-K), this value is higher relative to conventional polymer thermal interface materials, and has a lower contact thermal resistance and a certain degree of mobility, the liquid metal 1052 can reduce the encapsulation thermal resistance, which in turn substantially improves the thermal diffusion efficiency in the encapsulation process, and improves the quality of the encapsulation.

In step S5, referring to FIG. 1, FIG. 7 and FIG. 8, a heat dissipation member is formed on the layer 105 of thermal interface material, and the heat dissipation member is sealed and fixed to the enclosure structure 1051.

Optionally, as shown in FIGS. 7 and 8, the heat dissipating component may comprise a heat dissipating cover 106 or a heat dissipating element 108, wherein the heat dissipating element 108 may comprise a heat dissipating base 1081 and heat dissipating fins 1082 uniformly arranged on the heat dissipating base 1081.

Optionally, the enclosure structure 1051 is hermetically sealed and connected to the heat dissipating member by the UV curing adhesive 104.

Specifically, when the heat dissipation component employs the heat dissipation cover plate 106, the UV curing adhesive 104 may be coated on the top of the enclosure structure 1051, the bottom of the sidewalls in the heat dissipation cover plate 106 that are to be bonded to the substrate 101, or the surface of the substrate 101 that corresponds to the substrate 101, respectively, and will be cured under the action of the UV light, so that the top of the enclosure structure 1051 in combination with the heat sink cover 106 can be sealed and fixedly connected to give sealing protection to the liquid metal 1052 and prevent the liquid metal 1052 from spilling.

Wherein, the heat generated by the chip 102 can be directly conducted to the heat dissipation cover 106 through the liquid metal 1052 and transferred to the outside through the heat dissipation cover 106 to realize the heat dissipation function. At the same time, as the heat dissipating cover plate 106 is bonded to the substrate 101 as a single piece, the structural strength of the substrate 101 is greatly improved, and the substrate 101 is able to keep its surface flush under the fixing effect of the UV curing adhesive 104 and the heat dissipating cover plate 106 to avoid warping of the substrate 101.

Optionally, as shown in FIG. 8, when the heat dissipation component employs the heat dissipation element 108, the heat dissipation base 1081 in the heat dissipation element 108 is directly sealed and fixedly connected to the enclosure structure 1051, so that the liquid metal 1052 can directly contact with the chip and the heat dissipation element 108 to realize good heat dissipation. Therein, it may include the step of dabbing the ultraviolet light curing adhesive 104 on top of the enclosure structure 1051, the ultraviolet light curing adhesive 104 will be cured under the action of ultraviolet light, realizing the sealing and fixing connection between the enclosure structure 1051 and the heat dissipation element 108, so as to realize the sealing of the liquid metal 1052, and preventing the encapsulation of the liquid metal 1052 and the use of the liquid metal 1052 from of overflow during encapsulation and use.

### Embodiment 2

This embodiment provides a chip packaging structure, the packaging structure comprising:
a substrate 101;
a chip 102, the chip 102 being disposed on the substrate 101 and electrically connected to the substrate 101;
an enclosure structure 1051 disposed on the chip 102, wherein a wall of the enclosure structure 1051 comprises a sealed cavity, and the chip 102 is revealed through the sealed cavity in the wall;
a layer 105 of thermal interface material for the chip 102, which is formed by filling a liquid metal 1052 into the sealed cavity of the wall of the enclosure structure 1051; and
a heat sink, formed on the layer 105 of thermal interface material, wherein the heat sink is hermetically sealed to the wall of the enclosure structure 1051.

With respect to the preparation of the chip package structure, reference may be made to the above preparation method, but it is not limited thereto, in this embodiment, the chip package structure is prepared by the above preparation method, and thus with respect to the preparation of the chip package structure, the selection of materials and the like, reference may be made to Embodiment I, which will not be repeated herein.

Optionally, as shown in FIG. 4, the chip package structure further comprises a dummy chip 103 connected to the substrate 101 at fixed locations and symmetrically distributed on both sides of the chip 102.

Optionally, as shown in FIGS. 7 and 8, the heat dissipation component comprises a heat dissipation cover 106 or a heat dissipation element 108, the heat dissipation element 108 comprising a heat dissipation base 1081, and heat dissipation fins 1082 disposed in a uniform arrangement on the heat dissipation base 1081.

Specifically, the thermal base 1081 is sealed and fixedly connected to the thermal interface material layer 105.

In summary, the present invention provides a chip packaging structure and a method for preparing the same. The chip packaging structure comprises: a substrate; a chip, the chip being disposed on the substrate and electrically connected to the substrate; a thermal interface material layer comprising an enclosure structure and a liquid metal filled in the enclosure structure, the thermal interface material layer being sealed and fixed to the chip by means of an ultraviolet curing adhesive; and a heat dissipation component formed on the thermal interface material layer and the heat dissipation component being sealed and fixed to the enclosure structure, comprising a heat dissipation cover plate or a heat dissipation element. The thermal interface material layer, and the heat dissipation component are sealed and fixedly connected to the enclosure structure, including a heat dissipation cover plate or heat dissipation element. The present invention reduces the thermal resistance of the encapsulation by introducing liquid metal as the thermal interface material, thereby substantially improving the thermal diffusion efficiency in the encapsulation process; the enclosure structure prepared using flexible materials prevents the liquid metal from overflowing in the encapsulation and application process, thereby reducing the probability of the resulting degradation of the electrical properties of the device, and the removal and replacement process is simple and effective due to the use of UV curing adhesive sealing to securely connect the thermal interface material layer. Replacement process is simple and effective. The present disclosure effectively addresses the limitations of existing technologies, making it highly valuable for industrial applications.

The embodiments described above serve merely as illustrative examples of the principles and effects of the present invention, and are not intended to serve as limitations on the present invention. Persons skilled in the art may modify or alter these embodiments without departing from the spirit and scope of the present disclosure. Accordingly, all equivalent modifications or alterations accomplished by persons having ordinary knowledge of the art without departing from the spirit and technical ideas disclosed herein shall still be covered by the claims of the present invention.

1. A method of preparing a chip package structure, comprising steps of:
providing a substrate;
bonding a chip to the substrate, wherein the chip is electrically connected to the substrate;
forming an enclosure structure to contain the chip in a fixed position, wherein a wall of the enclosure structure comprises a sealed cavity, and the chip is revealed through the sealed cavity in the wall;
filling the sealed cavity in the wall of the enclosure structure with a liquid metal to form a layer of thermal interface material for the chip; and
forming a heat sink on the layer of thermal interface material, wherein the heat sink is hermetically sealed to the wall of the enclosure structure.

2. The method of preparation the chip package structure according to claim 1, further comprising a step of forming dummy chips connecting to the substrate, wherein the dummy chips are symmetrically placed at fixed locations on both sides of the chip.

3. The method of preparation the chip package structure according to claim 1, wherein a material of the liquid metal comprises one of gallium, indium or tin.

4. The method of preparation the chip package structure according to claim 1, wherein the enclosure structure comprises a flexible material, comprising one of foam, PDMS (polydimethylsiloxane), or EPDM (ethylene propylene diene rubber).

5. The method of preparation the chip package structure according to claim 1, wherein the heat sink comprises a heat dissipating element, comprising a heat dissipation cover plate and a dissipation element, which includes a heat dissipation base and heat dissipation fins arranged uniformly on the heat dissipation base.

6. The method of preparation the chip package structure according to claim 1, wherein the enclosure structure is attached to the chip by means of a UV curing adhesive; and the wall of the enclosure structure is hermetically sealed to the heat sink by means of a UV curing adhesive.

7. The method of preparation the chip package structure according to claim 1, wherein the substrate comprises a wafer.

8. A chip package structure comprising:
a substrate;
a chip disposed on the substrate and electrically connected to the substrate;
an enclosure structure disposed on the chip, wherein a wall of the enclosure structure comprises a sealed cavity, and the chip is revealed through the sealed cavity in the wall;
a layer of thermal interface material for the chip, which is formed by filling a liquid metal into the sealed cavity of the wall of the enclosure structure; and
a heat sink, formed on the layer of thermal interface material, wherein the heat sink is hermetically sealed to the wall of the enclosure structure.

9. The chip package structure according to claim 8, further comprising dummy chips attached to the substrate, wherein the dummy chips are symmetrically placed at fixed locations on both sides of the chip.

10. The chip package structure according to claim 8, wherein the sink comprises a heat dissipation cover plate and a dissipation element, which includes a heat dissipation base and heat dissipation fins arranged uniformly on the heat dissipation base.
